(19) United States
(12) Patent Application Publication
(10) Pub. No.: US 2009/0273005 A1
(43) Pub. Date: Nov. 5, 2009

(54) OPTO-ELECTRONIC PACKAGE STRUCTURE HAVING SILICON-SUBSTRATE AND METHOD OF FORMING THE SAME

(76) Inventor: Hung-Yi Lin, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 12/499,804

(22) Filed: Jul. 9, 2009

Related U.S. Application Data
(63) Continuation-in-part of application No. 11/611,892, filed on Dec. 18, 2006, now abandoned.

(30) Foreign Application Priority Data
Jul. 24, 2006 (TW) 095126950

(51) Int. Cl. H01L 33/00; H01L 21/50

(52) U.S. Cl. 257/99; 438/26; 257/103; 257/98; 257/E33.075; 257/E33.066; 257/E21.499

(57) ABSTRACT

Disclosed herein is a structure of opto-electronic package having a Si-substrate. The Si-substrates are manufactured in batch utilizing the micro-electromechanical processes or the semiconductor processes, so that these Si-substrates are made with great precision and full of varieties. Based on the material characteristic of the Si-substrate, and the configuration of the components, such as the connectors, opto-electronic devices, depressions, solder bumps, etc., the present invention can improve the optical effect, the heat dissipating effect, and the reliability of the opto-electronic package structure, and simplifies the complexity of the opto-electronic package structure.

### CROSS REFERENCE TO RELATED APPLICATIONS

This is a continuation-in-part of U.S. patent application Ser. No. 11/611,892, filed Dec. 18, 2006.

### BACKGROUND OF THE INVENTION

1. Field of the Invention

The present invention generally relates to the field of opto-electronic package structures, and more particularly, to an opto-electronic package structure formed by the micro-electromechanical processes or the semiconductor processes.

2. Description of the Prior Art

In recent years, a new application field of high illumination light emitting diodes (LEDs) has been developed. Different from a common incandescent light, a cold illumination LED has the advantages of low power consumption, long device lifetime, no idling time, and quick response speed. In addition, since the LED also has the advantages of small size, vibration resistance, suitability for mass production, and ease of fabrication as a tiny device or an array device, it has been widely applied in display apparatuses and indicating lamps used in information, communication, and consumer electronic products. The LEDs are not only utilized in outdoor traffic signal lamps or various outdoor displays, but are also very important components in the automotive industry. Furthermore, the LEDs work well in portable products, such as cellular phones and as backlights of personal data assistants. These LEDs have become necessary key components in the highly popular liquid crystal displays because they are the best choice when selecting the light source of the backlight module.

Please refer to FIG. 1 and FIG. 2. FIG. 1 is a schematic top view diagram showing a prior art surface mount device (SMD) LED package structure 10, and FIG. 2 is a cross section diagram illustrating the prior art SMD LED package structure 10 along 1-1′ line shown in FIG. 1. As shown in FIG. 1 and FIG. 2, an SMD LED package structure 10 comprises a cup-structure substrate 12, a lead frame 14, an opto-electronic device 16, conducting wires 18 and 20, and a sealant 22. As a semiconductor device comprising a positive electrode and a negative electrode (not shown), the opto-electronic device 16 is illuminated by receiving power from an external voltage source and connected to the lead frame 14 by the conducting wires 18 and 20. Situated in the cup-structure substrate 12, the lead frame 14 is extended to the outer surface of the cup-structure substrate 12, which will be electrically connected to a printed circuit board (PCB) 24.

In order to construct the prior art LED package 10, the cup-structure substrate 12 should be completed first, and then the sealant 22 covers the opto-electronic device 16 by means of molding or sealant injection. After the construction of the prior art LED package 10 is completed, at least a surface mounting process is performed to mount the LED packages 10 on the PCB 24 individually. As a result, it is almost impossible to produce the LED packages 10 in batch, and the manufacturing process of the electronic products is too complicated and tedious. As applied in a LED package 10 with high power, the cup-structure substrate 12 of the opto-electronic device 16 is unavoidably overheated, which may eventually result in a reduction of light intensity or failure of the entire device. Due to the significantly large volume of the single LED package 10 and the heat radiating demand required by a LED package 10 with high power, the designed size and the heat dissipating efficiency of the whole LED package 10 are greatly limited.

### SUMMARY OF THE INVENTION

It is the primary object of the present invention to provide an opto-electronic package structure having a Si-substrate. Accordingly, the present invention can improve the optical effect, the heat dissipating effect, and the reliability of the opto-electronic package structure, the opto-electronic package structure can be manufactured in batch, and the complexity of the opto-electronic package structure can be simplified.

According to the claimed invention, an opto-electronic package structure having a Si-substrate is disclosed. The opto-electronic package structure includes a Si-substrate having a top surface and a bottom surface, a plurality of connectors and at least an opto-electronic device positioned on the top surface of the Si-substrate. The Si-substrate includes a plurality of electric-conducting holes and a plurality of heat-conducting holes. Each of the electric-conducting holes penetrates through the Si-substrate from the top surface to the bottom surface, and each of the heat-conducting holes penetrating through the Si-substrate from the top surface to the bottom surface. The connectors include a plurality of substrate-penetrating electric-conducting wires and at least a heat-conducting wire. Each of the substrate-penetrating electric-conducting wires extends from the top surface of the Si-substrate to the bottom surface of the Si-substrate through the electric-conducting holes, and the heat-conducting wire covers portions of the bottom surface of the Si-substrate. The heat-conducting wire extends from the top surface of the Si-substrate to the bottom surface of the Si-substrate through the heat-conducting holes. The opto-electronic device covers and adjusts the heat-conducting holes, corresponds to the heat-conducting wire, and is electrically connected to the substrate-penetrating electric-conducting wires.

From one aspect of the present invention, a method of forming an opto-electronic package structure having a Si-substrate is disclosed. First, a Si-substrate and a first patterned isolation layer covering at least a surface of the Si-substrate are provided. Subsequently, the Si-substrate is etched through openings of the first patterned isolation layer to form a plurality of electric-conducting holes and a plurality of heat-conducting holes. Each of the electric-conducting holes and each of the heat-conducting holes penetrate through the Si-substrate from the top surface to the bottom surface. Next, a patterned conductive layer filling the electric-conducting holes and the heat-conducting holes is formed to form a plurality of substrate-penetrating electric-conducting wires and at least a heat-conducting wire respectively. Each of the substrate-penetrating electric-conducting wires and the heat-conducting wire extend from the top surface of the Si-substrate to the bottom surface of the Si-substrate through the electric-conducting holes and the heat-conducting holes respectively. The heat-conducting wire covers portions of the bottom surface of the Si-substrate, wherein the substrate-penetrating electric-conducting wires and the heat-conducting wire are electrically disconnected. Furthermore, at least an opto-electronic device is provided on the top surface of the Si-substrate. The opto-electronic device covers and adjusts the heat-conducting holes, corresponds to the heat-conducting wire, and is electrically connected to the substrate-penetrating electric-conducting wires.

Since the Si-substrates can be produced in a batch system utilizing micro-electromechanical processes or semiconductor processes, these Si-substrates are made with great precision and full of varieties. According to the characteristics of Si-substrate and the arrangement of the components, such as the connectors, the opto-electronic device, the cup-structure and the flip-chip bump on Si-substrate, the present invention can simplify the complexity of the components in the opto-electronic package structure, and increase the optical effect, the heat-dissipating effect and the packaging reliability of the opto-electronic package structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view diagram showing a prior art surface mount device (SMD) LED package structure.

FIG. 2 is a cross section diagram illustrating the prior art SMD LED package structure along 1-1′ line shown in FIG. 1.

FIG. 3 is a schematic cross-sectional diagram illustrating an opto-electronic package structure having a Si-substrate according to a first preferred embodiment of the present invention.

FIG. 4 is a schematic top view of the opto-electronic package structure shown in FIG. 3.

FIG. 5 is a schematic diagram illustrating an opto-electronic package structure having a Si-substrate according to a second preferred embodiment of the present invention.

FIG. 6 is a cross-sectional schematic diagram illustrating the opto-electronic package structure along line 5-5′ shown in FIG. 5.

FIG. 7 through FIG. 10 are schematic cross-sectional diagrams illustrating a method of forming an opto-electronic package structure having a Si-substrate according to a third preferred embodiment of the present invention.

FIG. 11 and FIG. 12 are schematic cross-sectional diagrams illustrating a method of forming an opto-electronic package structure having a Si-substrate according to a fourth preferred embodiment of the present invention.

FIG. 13 and FIG. 14 are schematic cross-sectional diagrams illustrating a method of forming an opto-electronic package structure having a Si-substrate according to a fifth preferred embodiment of the present invention.

FIG. 15 is a schematic tip-view diagram illustrating the heat-conducting wire according to the sixth preferred embodiment of the present invention.

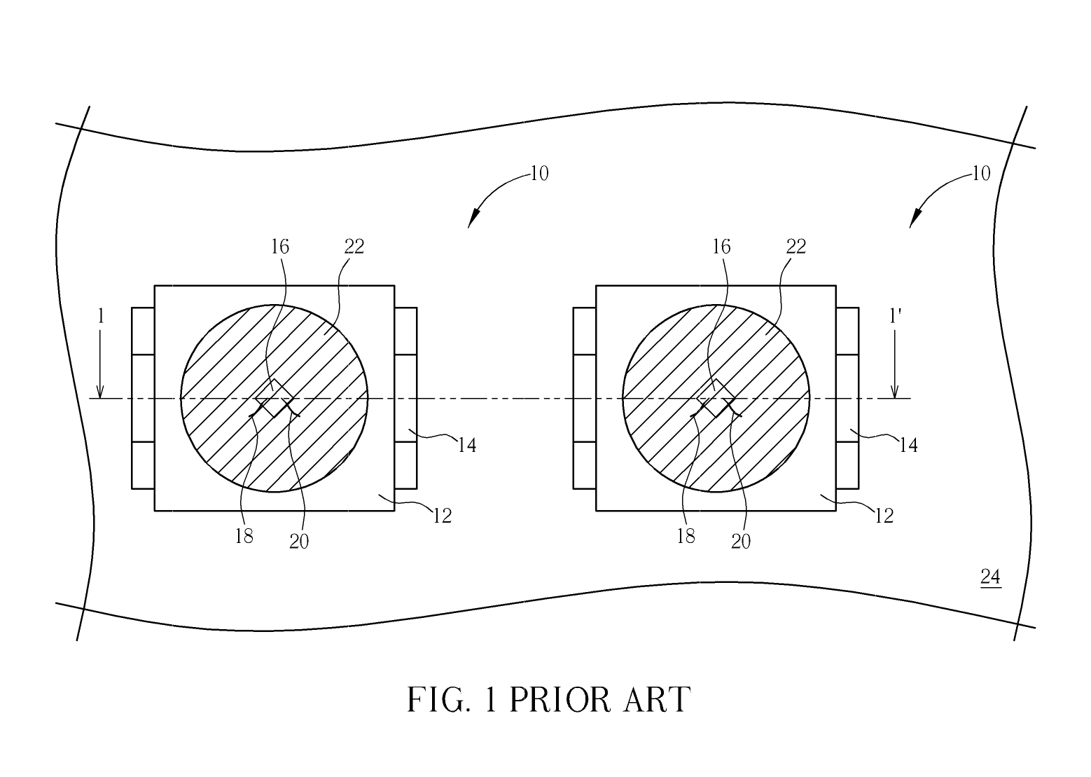

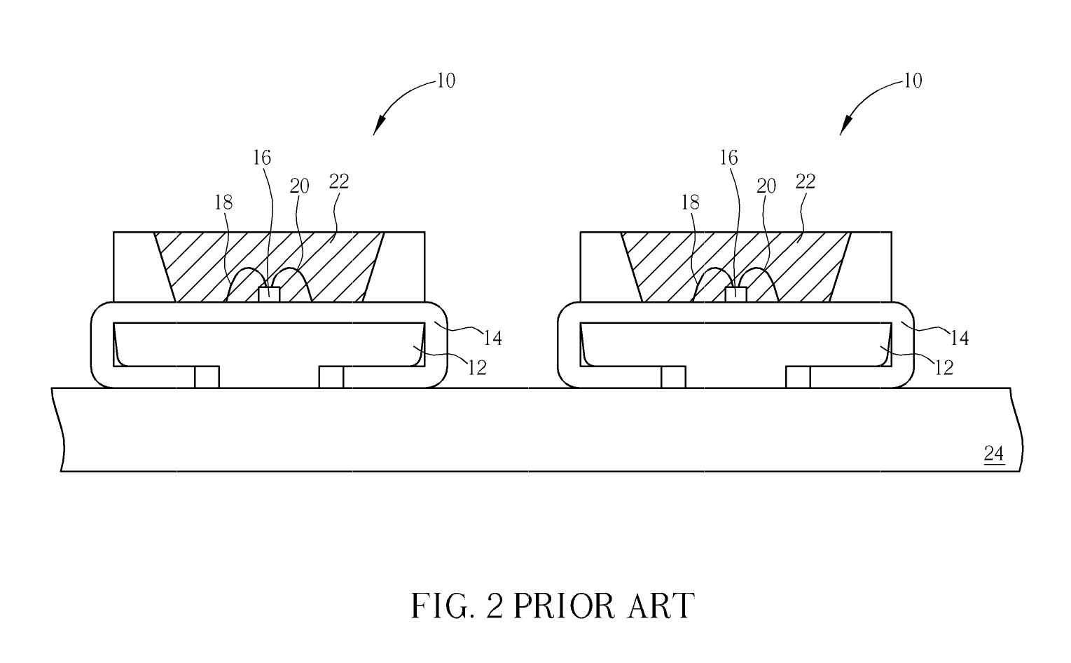

### DETAILED DESCRIPTION

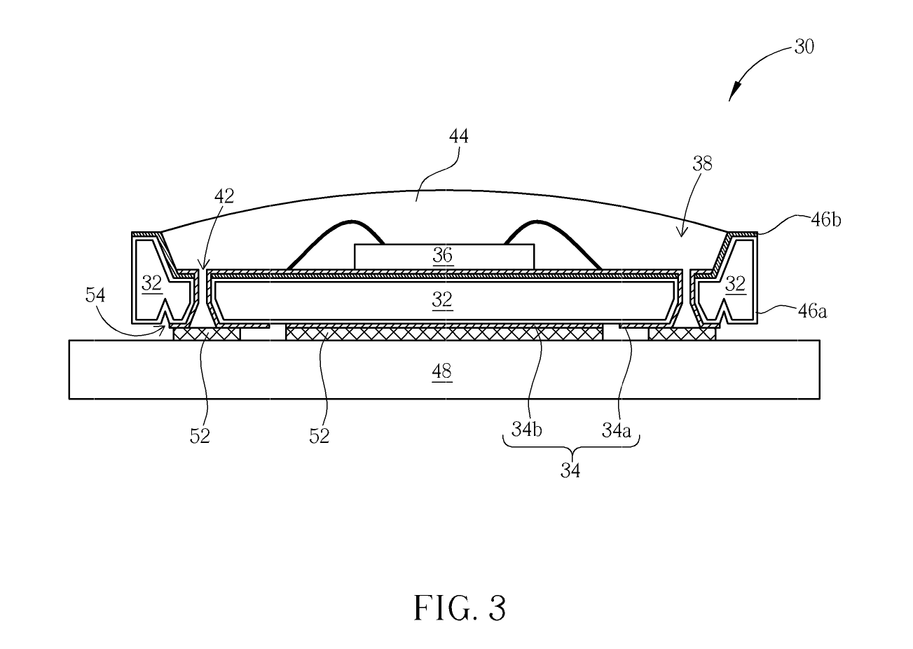

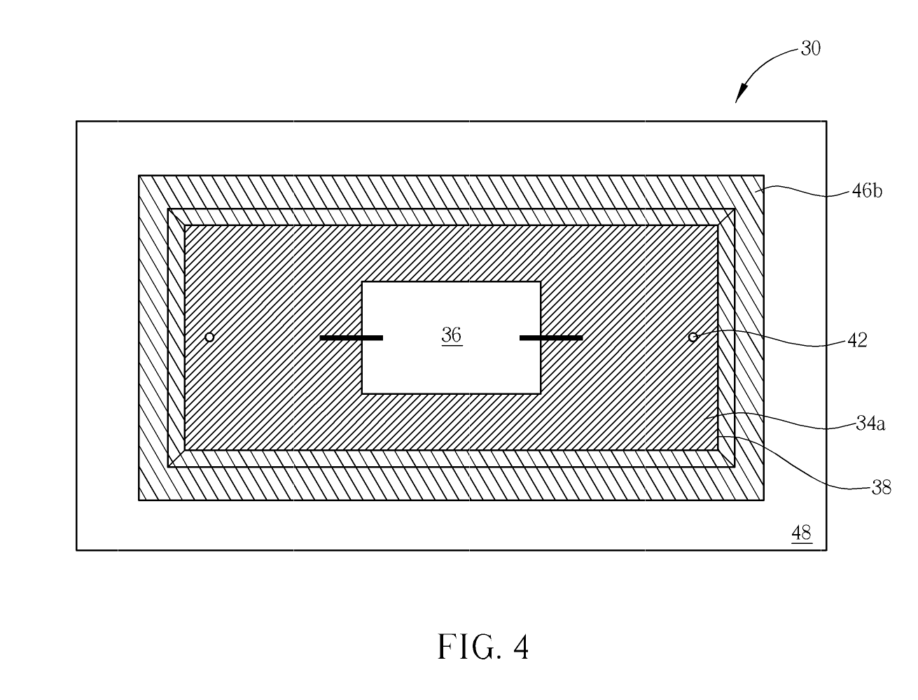

Please refer to FIG. 3 and FIG. 4. FIG. 3 is a schematic cross-sectional diagram illustrating an opto-electronic package structure 30 having a Si-substrate 32 according to a first preferred embodiment of the present invention, and FIG. 4 is a schematic top view of the opto-electronic package structure 30 shown in FIG. 3. It is to be understood that the drawings are not drawn to scale and are used only for illustration purposes. As shown in FIG. 3 and FIG. 4, an opto-electronic package structure 30 includes a Si-substrate 32, a plurality of connectors 34 and at least an opto-electronic device 36. The material of the Si-substrate 32 includes polysilicon, amorphous silicon or single-crystal silicon. In addition, the Si-substrate 32 can be a rectangle silicon chip or a circular silicon chip, and can include integrated circuits or passive components therein. The Si-substrate 32 has a top surface and a bottom surface. A cup-structure 38 can be included on the top surface of the Si-substrate 32 for having a capacity of the opto-electronic device 36. The Si-substrate 32 can control the optical effect of the opto-electronic package structure 30 by means of some factors, such as the position of cup-structure 38, the hollow depth of cup-structure 38, the hollow width of cup-structure 38 and the sidewall shape of cup-structure 38. A plurality of electric-conducting holes 42 can be included in the Si-substrate 32, and each electric-conducting hole 42 penetrates through the Si-substrate 32 from the top surface to the bottom surface.

The connectors 34 include a plurality of substrate-penetrating electric-conducting wires 34a and at least a heat-conducting wire 34b. The substrate-penetrating electric-conducting wires 34a and the heat-conducting wire 34b can be formed in the meantime utilizing a micro-electromechanical process or a semiconductor process, such as a plating process or a deposition process. For forming the substrate-penetrating electric-conducting wires 34a and the heat-conducting wire 34b, a metal layer is formed on the top surface of the Si-substrate 32, the bottom surface of the Si-substrate 32 and sidewalls of the electric-conducting holes 42 first. Thereafter, the substrate-penetrating electric-conducting wires 34a and the heat-conducting wire 34b are separated by means of an etching process so that the substrate-penetrating electric-conducting wires 34a and the heat-conducting wire 34b do not electrically connect to each other. Each substrate-penetrating electric-conducting wire 34a extends from the top surface of the Si-substrate 32 to the bottom surface of the Si-substrate 32 through at least one of the electric-conducting holes 42. The heat-conducting wire 34b covers portions of the bottom surface of the Si-substrate 32, and is preferably located in a position corresponding to the opto-electronic device 36. Specifically speaking, the heat-conducting wire 34b can be a flat metal layer having large area, and each substrate-penetrating electric-conducting wire 34a can be a flat metal layer having large area or a metal circuit layer having circuit therein.

The opto-electronic device 36 can be a light-emitting component or a photo sensor, such as a light emitting diode (LED), a photo diode, a digital micro mirror device (DMD), or a liquid crystal on silicon (LCOS), but is not limited to those devices. The opto-electronic device 36 can be fixed onto the top surface of the Si-substrate 32 by a fixing gel. Furthermore, the positive electrode and negative electrode of the opto-electronic device 36 are then connected individually to the positive electrode terminal and the negative electrode terminal defined on the substrate-penetrating electric-conducting wires 34a, using a wire bonding technique or a flip-chip technique.

In addition to above-mentioned components, the opto-electronic package structure 30 of the present invention can further include a packaging material layer 44, an insulation layer 46a and an optical film 46b. The packaging material layer 44 is composed of mixtures containing resin, wavelength converting materials, fluorescent powder, and/or light-diffusing materials. Next, the packaging material layer 44 is packaged onto the Si-substrate 32 by a molding or sealant injection method so as to increase the product reliability of the opto-electronic package structure 30, and to control the optical effect of the opto-electronic device 36. The optical film 46b can be a coat having a high refractive index located on the bottom and the sidewall of the cup-structure 38, and it can further increase the light quantity propagating from the opto-electronic package structure 30 in combination with the cup-structure 38.

Through the substrate-penetrating electric-conducting wires 34a on the bottom surface of the Si-substrate 32, the opto-electronic package structure 30 can be connected onto a printed circuit board 48 by means of surface mounting. The printed circuit board 48 can be a glass fiber reinforced polymeric material, such as ANSI Grade. FR-1, FR-2, FR-3, FR-4 or FR-5, or a metal core printed circuit board. According to its concrete mounting process, a solder paste can first be formed on the surface of the printed circuit board 48 to be a metal connecting layer 52. The metal connecting layer 52 corresponds to and connects with the substrate-penetrating electric-conducting wires 34a and the heat-conducting wire 34b positioned on the bottom surface of the opto-electronic package structure 30. Therefore, the opto-electronic package structure 30 can electrically connect to the printed circuit board 48 through the substrate-penetrating electric-conducting wires 34a and the metal connecting layer 52. On the other hand, in order to form a structure having different conducting paths for heat and for electrons, the produced heat of the opto-electronic device 36 can be transmitted to the surroundings through the heat conducting path constituted by the Si-substrate 32, the heat-conducting wire 34b, the metal connecting layer 52 and the printed circuit board 48. Once the metal connecting layer 52 is squeezed or the position of the metal connecting layer 52 deviates, the metal connecting layer 52 might get in touch with other components, and cause a short circuit. In order to prevent the metal connecting layer 52 from contacting with other components, the bottom surface of the Si-substrate 32 in the present invention can further include a plurality of trenches 54 to accept the unnecessary solder paste. Thus, the occurring probability of the short between the metal connecting layer 52 and other components can be easily reduced without using the expensive wafer having a high resistance.

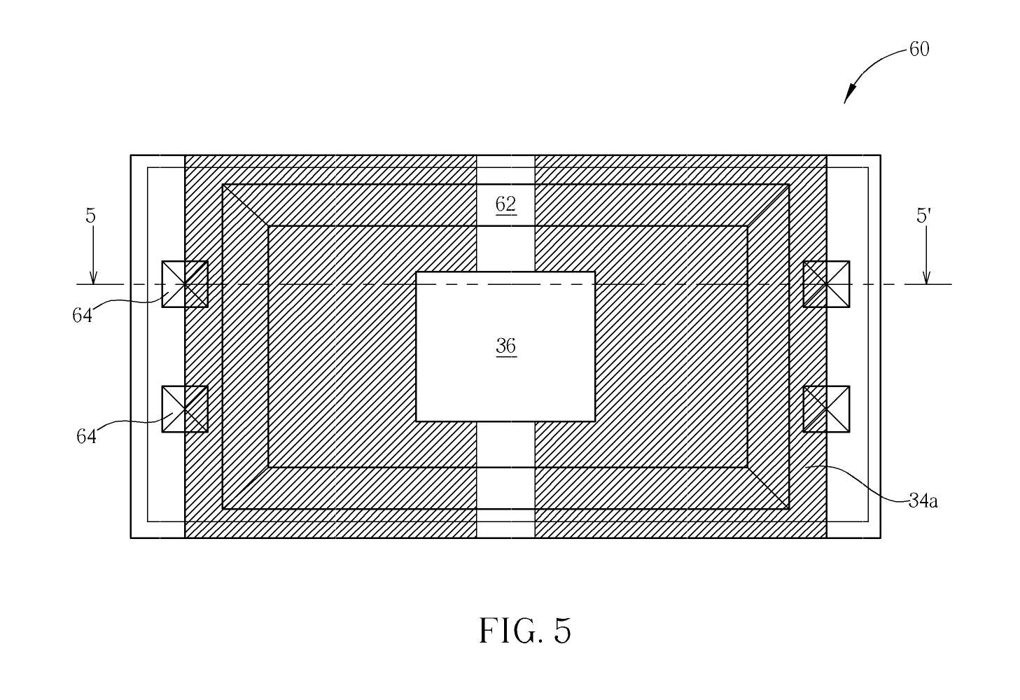

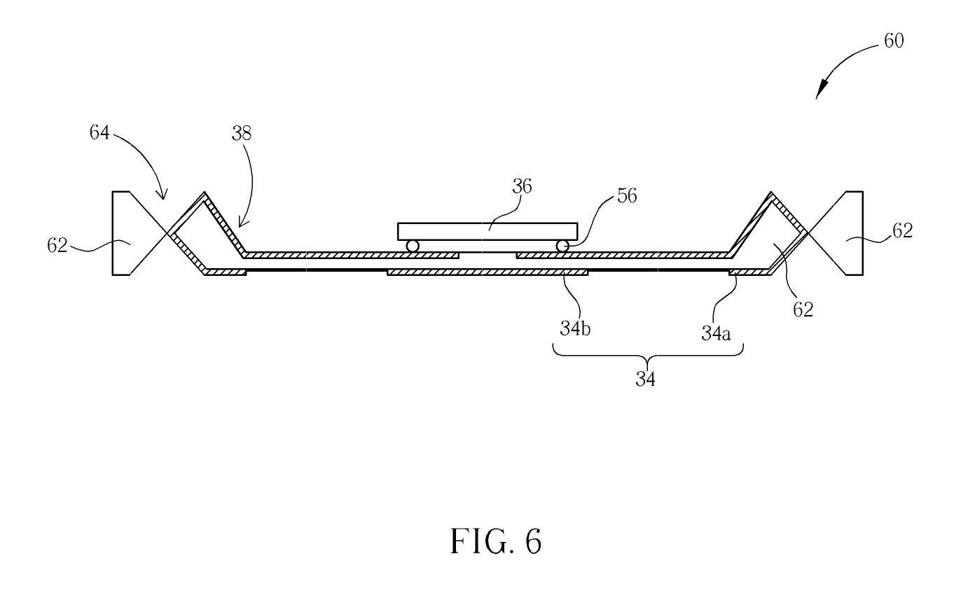

The opto-electronic package structure of the present invention can be arranged in other forms according to other embodiments. Please refer to FIG. 5 and FIG. 6. FIG. 5 is a schematic diagram illustrating an opto-electronic package structure 60 having a Si-substrate 62 according to a second preferred embodiment of the present invention, and FIG. 6 is a cross-sectional schematic diagram illustrating the opto-electronic package structure 60 along line 5-5′ shown in FIG. 5, wherein like number numerals designate similar or the same parts, regions or elements. As shown in FIG. 5 and FIG. 6, an opto-electronic package structure 60 includes a Si-substrate 62, a plurality of connectors 34 and at least an opto-electronic device 36. The material of the Si-substrate 62 includes polysilicon, amorphous silicon or single-crystal silicon, and can include integrated circuits or passive components therein. A cup-structure 38 is included in the top surface of the Si-substrate 62 so as to contain the opto-electronic device 36 therein.

The connectors 34 include a plurality of substrate-penetrating electric-conducting wires 34a and can further include at least a heat-conducting wire 34b. In order to form the substrate-penetrating electric-conducting wires 34a and the heat-conducting wire 34b simultaneously, a metal layer is first formed on the top surface of the Si-substrate 62, the bottom surface of the Si-substrate 62 and sidewalls of the electric-conducting holes 64 utilizing a plating process or a deposition process. Next, the substrate-penetrating electric-conducting wires 34a and the heat-conducting wire 34b are separated by means of an etching process so that the substrate-penetrating electric-conducting wires 34a and the heat-conducting wire 34b do not electrically connect to each other. Each substrate-penetrating electric-conducting wire 34a extends from the top surface of the Si-substrate 62 to the bottom surface of the Si-substrate 62 through at least one of the electric-conducting holes 64. The heat-conducting wire 34b covers portions of the bottom surface of the Si-substrate 62, and is preferably located in a position corresponding to the opto-electronic device 36. In application, the heat-conducting wire 34b can be a flat metal layer having large area, and each substrate-penetrating electric-conducting wire 34a can be a flat metal layer having large area or a metal circuit layer having circuit therein.

The positive electrode and negative electrode of the opto-electronic device 36 can first be connected individually to the positive electrode terminal and the negative electrode terminal defined on the substrate-penetrating electric-conducting wires 34a through a plurality of solder bumps 56. Subsequently, the positive electrode and negative electrode of the opto-electronic device 36 are connected to a printed circuit board (not shown in the figure) through the substrate-penetrating electric-conducting wires 34a positioned on the bottom surface of the Si-substrate 62. Additionally, in order to form a structure having different conducting paths for heat and for electrons, the opto-electronic device 36 can transmit the produced heat to the surroundings through the heat conducting path constituted by the Si-substrate 62, the heat-conducting wire 34b and the printed circuit board.

It should be noticed that the electric-conducting holes 42 of the first preferred embodiment penetrate parts of the Si-substrate 32 positioned under the cup-structure 38, and the electric-conducting holes 64 of this embodiment penetrate parts of the Si-substrate 32 positioned around the cup-structures 38. Because the electric-conducting holes 64 of this embodiment are located around the cup-structure 38, the surface in the bottom and in the sidewall of the cup-structure 38 can be completely covered with the substrate-penetrating electric-conducting wires 34a of the connectors 34. According to this arrangement, the substrate-penetrating electric-conducting wires 34a can promote light effect, electric effect and heat effect in the meantime. In addition to providing electric conducting path, the metal of the substrate-penetrating electric-conducting wires 34a can also provide excellent reflecting effect, and increase an optical benefit. The substrate-penetrating electric-conducting wires 34a having metal material can even directly function as an optical film. Furthermore, the substrate-penetrating electric-conducting wires 34a formed by metal material has a great heat transfer coefficient, so the heat generated in the opto-electronic package structure 60 can be dissipated easily.

A plurality of Si-substrates can be formed on one wafer utilizing micro-electromechanical processes or semiconductor processes in the meantime. As a result, these opto-electronic package structures can be produced in a batch system. After all components of the above-mentioned opto-electronic package structure are completed, the Si-substrates can be separated from each other by means of a wafer sawing process, and each opto-electronic package structure is electrically connected to the corresponding printed circuit board through the connectors of each Si-substrate. Therefore, the present invention benefits from low cost and consistency with standard micro-electromechanical processes and semiconductor processes.

The opto-electronic package structure according to the present invention is substantially characterized by including the substrate-penetrating electric-conducting wires and the heat-conducting wire. Since each of the substrate-penetrating electric-conducting wires extends from the top surface of the Si-substrate to the bottom surface of the Si-substrate through the electric-conducting holes, the opto-electronic package structure can electrically connect to the printed circuit board directly, and the whole volume of the opto-electronic package structure can be effectively reduced. Because the opto-electronic package structure is a structure having different conducting paths for heat and for electrons, heat generated from the opto-electronic device can be transferred through the heat-conducting path mainly, and the temperatures of the substrate-penetrating electric-conducting wires and of the opto-electronic device are decreased. Therefore, the electric-conduction of the substrate-penetrating electric-conducting wires and the operation of the opto-electronic device will be protected.

Because the present invention chooses the Si-substrate to form the opto-electronic package structure, and the heat transfer coefficient of silicon material is quite large, the heat-dissipating effect of the opto-electronic package structure can be increased. In addition, since silicon and an LED are both made from semiconductor materials, the coefficient of thermal expansion (CTE) of silicon is approximately equal to the CTE of the LED. Therefore, using silicon to form the packaging substrate can increase the reliability of the produced opto-electronic package structure.

Furthermore, the opto-electronic package structure having the Si-substrate can be made in a batch system utilizing micro-electromechanical processes or semiconductor processes. According to the characteristics of Si-substrate and the arrangement of the components, such as the connectors, the opto-electronic device, the cup-structure and the flip-chip bump on Si-substrate, the present invention can simplify the complexity of the components in the opto-electronic package structure, and increase the optical effect, the heat-dissipating effect and the packaging reliability of the opto-electronic package structure.

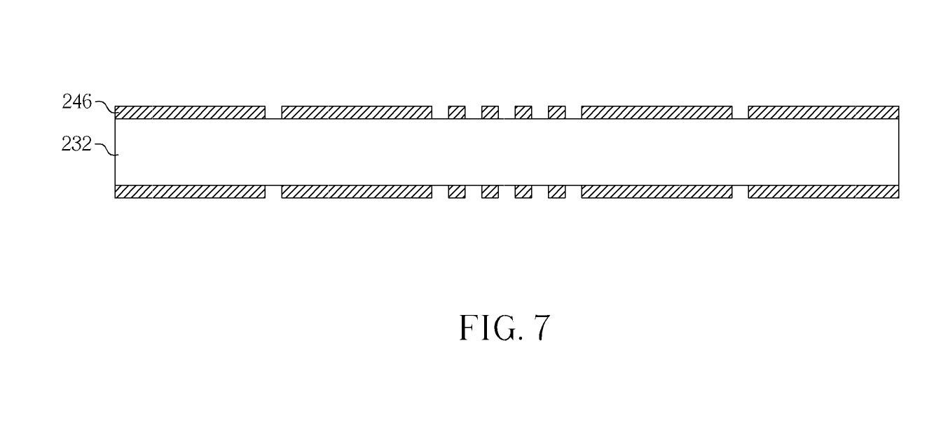

Please refer to FIG. 7 through FIG. 10. FIG. 7 through FIG. 10 are schematic cross-sectional diagrams illustrating a method of forming an opto-electronic package structure 230 having a Si-substrate 232 according to a third preferred embodiment of the present invention. As shown in FIG. 7, a Si-substrate 232 and a first patterned isolation layer 246 covering at least a surface of the Si-substrate 232 are first provided. The openings of the first patterned isolation layer 246 may define the positions of the following electric-conducting holes and the following heat-conducting holes.

The Si-substrate 232 may be a part of wafer, and is substantially a flat plat in this embodiment. The first patterned isolation layer 246 may be oxide layer formed by performing a thermal process on the Si-substrate 232 to oxidize surface parts of the Si-substrate 232 into an isolation layer, and thereafter performing a pattern process, such as a lithographic and etching process or a laser process, on the isolation layer to form the first patterned isolation layer 246. In other embodiments, the first patterned isolation layer 246 may be formed by forming a patterned photoresist on the Si-substrate 232 first, thereafter performing a thermal process on the Si-substrate 232 to oxidize surface parts of the Si-substrate 232 into the first patterned isolation layer 246, and afterward removing the patterned photoresist. In replacing steps, the first patterned isolation layer 246 may be formed by forming a patterned photoresist on the Si-substrate 232 first, thereafter performing a depositing process on the Si-substrate 232 to form the first patterned isolation layer 246, and afterward removing the patterned photoresist. The first patterned isolation layer 246 may include other isolative materials, such as nitride.

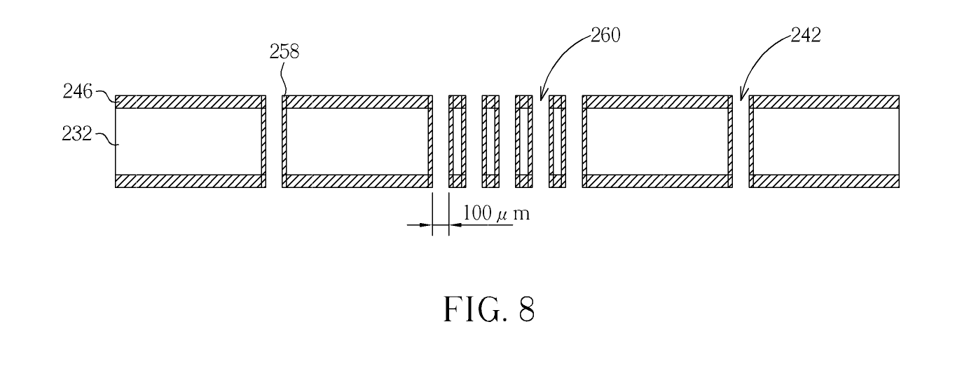

As shown in FIG. 8, subsequently, the Si-substrate 232 is etched through the openings of the first patterned isolation layer 246 to form a plurality of electric-conducting holes 242 and a plurality of heat-conducting holes 260. Each of the electric-conducting holes 242 and each of the heat-conducting holes 260 penetrate through the Si-substrate 232 from the top surface to the bottom surface. That is called through-silicon via (TSV) technology. Following that, a second isolation layer 258 is formed on sidewalls of the electric-conducting holes 242 and sidewalls of the heat-conducting holes 260.

Since the etching target is made of silicon, semiconductor etching processes can be adopted. For through-holes corresponding to the openings of the first patterned isolation layer 246, an anisotropic dry etching process, such as plasma etching process or reactive ion etch (RIE) process. Accordingly, the aperture of each heat-conducting hole 260 can be substantially in a range from 30 micrometers to 300 micrometers, preferably 50 micrometers to 100 micrometers, and a distance between two heat-conducting holes 260 can be substantially in a range from 10 micrometers to 50 micrometers, preferably 20 micrometers.

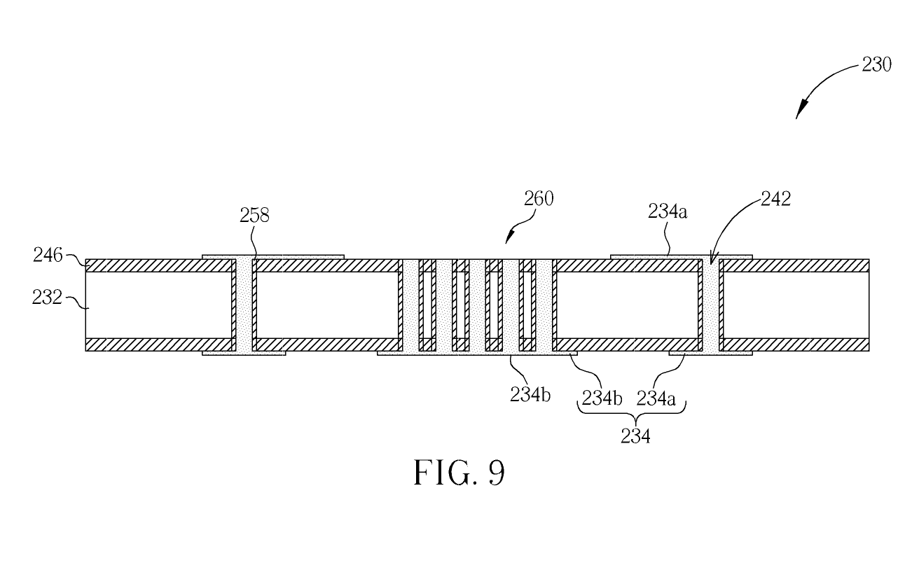

As shown in FIG. 9, a patterned conductive layer 234 filling the electric-conducting holes 242 and the heat-conducting holes 260 is next formed to form a plurality of substrate-penetrating electric-conducting wires 234a and at least a heat-conducting wire 234b respectively. Each of the substrate-penetrating electric-conducting wires 234a and the heat-conducting wire 234b extend from the top surface of the Si-substrate 232 to the bottom surface of the Si-substrate 232 through the electric-conducting holes 242 and the heat-conducting holes 260 respectively. The heat-conducting wire 234b covers portions of the bottom surface of the Si-substrate 232. The substrate-penetrating electric-conducting wires 234a and the heat-conducting wire 234b are electrically disconnected.

The step of forming the patterned conductive layer 234 can include forming a seed layer on surfaces of the first and second patterned isolation layers 246, 258; next performing a plating process to form conductive material on the seed layer until filling the electric-conducting holes 242 and the heat-conducting holes 260; and thereafter performing a patterning process to form the patterned conductive layer 234. In replacing steps, the patterned conductive layer 234 can be formed by forming a patterned photoresist on the first patterned isolation layer 246; next forming a seed layer on the exposed surfaces of the first and second patterned isolation layers 246, 258; thereafter performing a plating process to form conductive material on the seed layer until filling the electric-conducting holes 242 and the heat-conducting holes 260; and next removing the patterned photoresist.

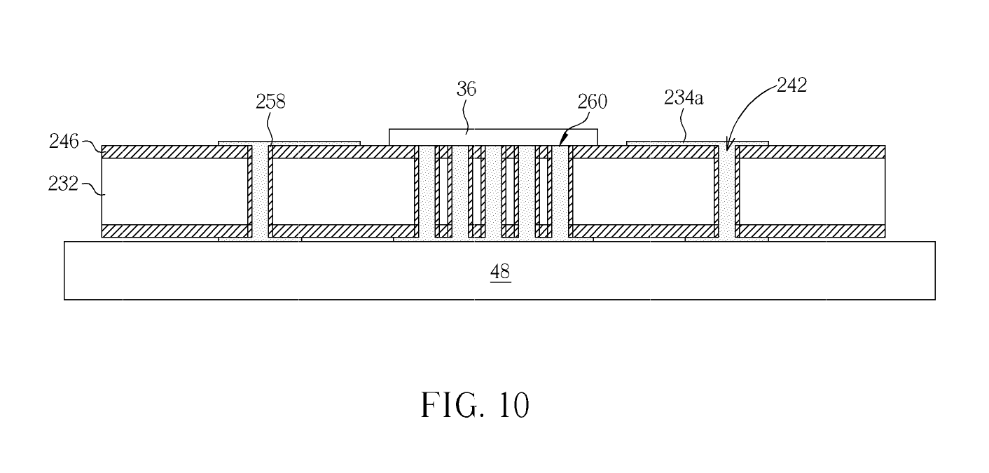

As shown in FIG. 10, furthermore, at least an opto-electronic device 36 is provided on the top surface of the Si-substrate 232. The opto-electronic device 36 covers and adjusts the heat-conducting holes 260, corresponds to the heat-conducting wire 234b, and is electrically connected to the substrate-penetrating electric-conducting wires 234a. Next, through the substrate-penetrating electric-conducting wires 234a on the bottom surface of the Si-substrate 232, the opto-electronic package structure 36 can be connected onto a printed circuit board 48 by means of surface mounting.

Since the aperture of each heat-conducting hole 260 can be substantially in a range from 30 micrometers to 300 micrometers, and a distance between two heat-conducting holes 260 can be substantially in a range from 10 micrometers to 50 micrometers, the fill factor of the heat-conducting wire 234b can be higher than 70% in the present invention, where the fill factor is a ratio of the total cross-section area of the heat-conducting wire 234b their selves to the total area contacting with the heat-generating device. In such a case, the thermal resistance of the following-formed opto-electronic package structure 230 can be reduced to 0.06° C./W, as the thermal resistance of the traditional ceramics package structure having heat-conducting wires is 0.15° C./W. The fill factor of the thermal heat-conducting wire in ceramics package structure can only be 22%.

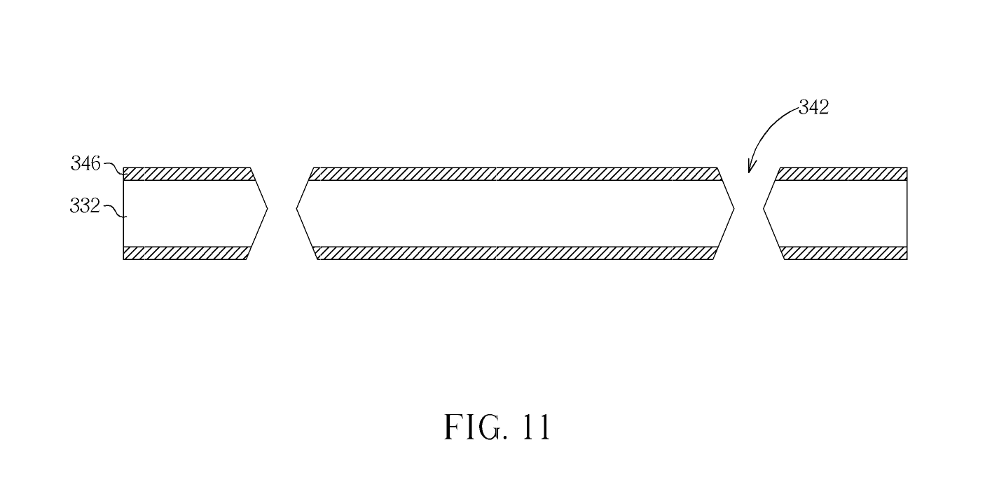

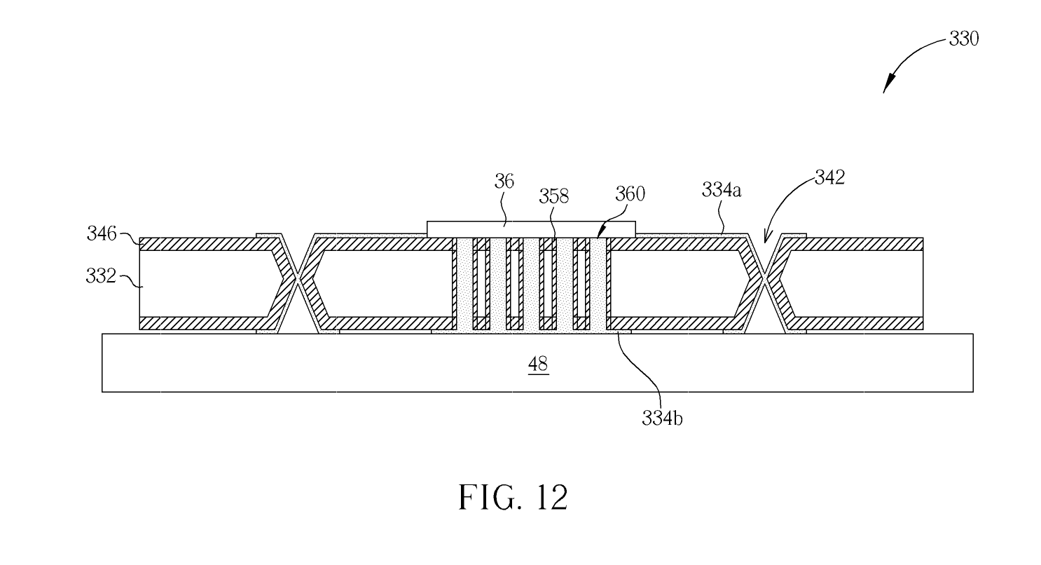

In the above embodiment, both the electric-conducting holes 242 and the heat-conducting holes 260 have vertical sidewalls. In other embodiment, the electric-conducting holes may have sidewalls in other shapes, such as the structure shown in FIG. 5. Please refer to FIG. 11 and FIG. 12. FIG. 11 and FIG. 12 are schematic cross-sectional diagrams illustrating a method of forming an opto-electronic package structure 330 having a Si-substrate 332 according to a fourth preferred embodiment of the present invention. As shown in FIG. 11, a Si-substrate 332 and a first patterned isolation layer 346 covering at least a surface of the Si-substrate 332 are first provided. The Si-substrate 332 may be a part of wafer, and is substantially a flat plat in this embodiment. The openings of the first patterned isolation layer 346 in FIG. 11 define the positions of the following electric-conducting holes. Subsequently, the Si-substrate 332 is next etched through the openings of the first patterned isolation layer 346 to form a plurality of electric-conducting holes 342 by performing a wet etching process. For example, the wet etching process may include potassium hydroxide (KOH) solution.

As shown in FIG. 12, the first patterned isolation layer 346 is further patterned to form openings for defining the positions of the following heat-conducting holes, and an anisotropic dry etching process is performed to form the heat-conducting holes 360. Each of the electric-conducting holes 342 and each of the heat-conducting holes 360 penetrate through the Si-substrate 332 from the top surface to the bottom surface. Following that, a second isolation layer 358, a plurality of substrate-penetrating electric-conducting wires 334a and at least a heat-conducting wire 334b are formed, and the opto-electronic package structure 36 and the printed circuit board 48 are provided, as described in the above-mentioned embodiment.

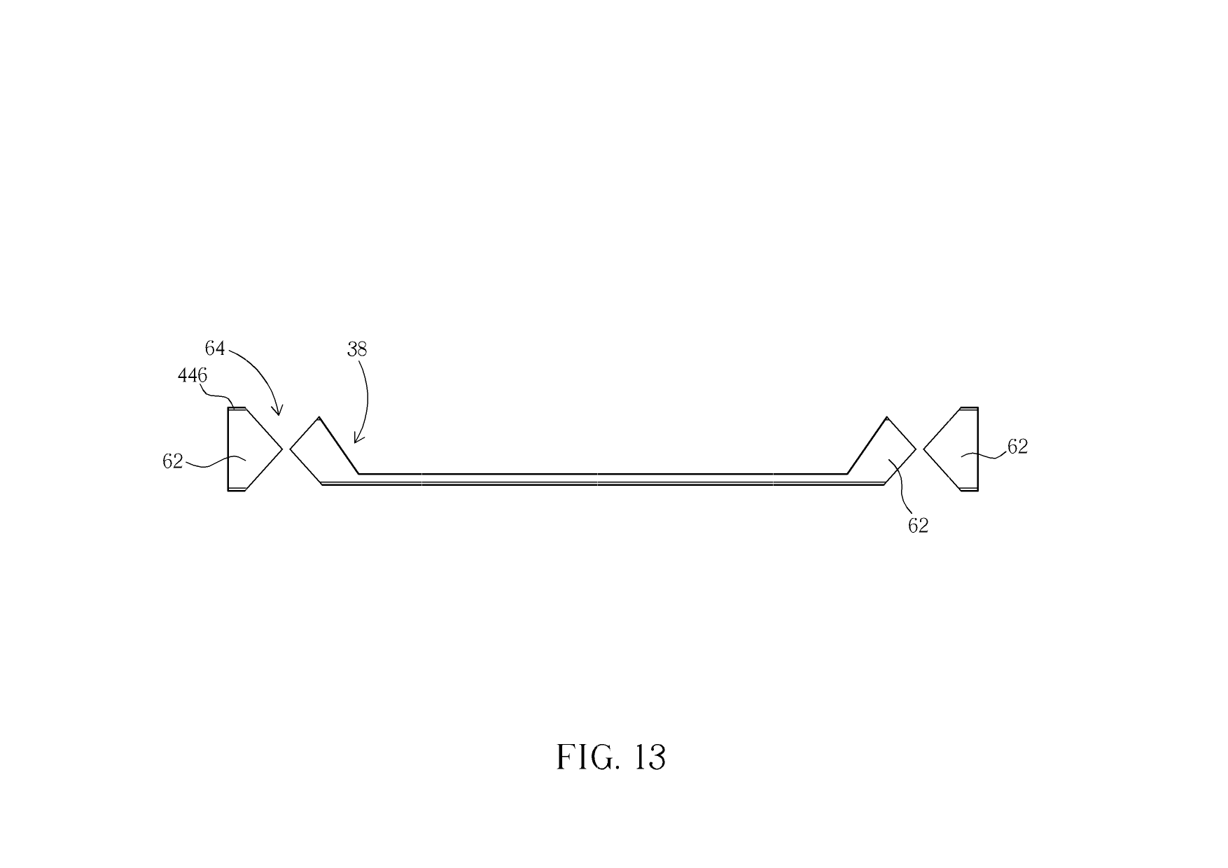

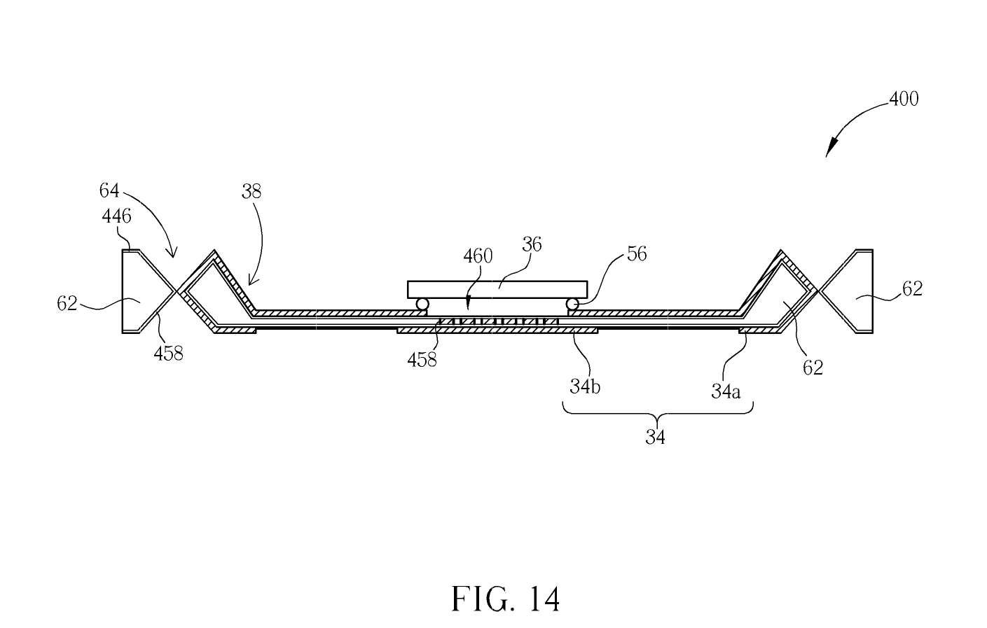

In the above-mentioned two embodiment, the Si-substrates 232, 332 are substantially a flat plat, so the top surfaces of the opto-electronic devices 36 are higher than the top surfaces of the Si-substrates 232, 332. In other embodiment, the top surface of the Si-substrate may include a cup-structure, and the opto-electronic device may be positioned in the cup-structure, such as the structure shown in FIG. 3 and FIG. 6. Please refer to FIG. 13 and FIG. 14. FIG. 13 and FIG. 14 are schematic cross-sectional diagrams illustrating a method of forming an opto-electronic package structure 400 having a Si-substrate 62 according to a fifth preferred embodiment of the present invention. As shown in FIG. 13, a Si-substrate 62 and a first patterned isolation layer 446 covering at least a surface of the Si-substrate 62 are first provided. The openings of the first patterned isolation layer 446 in FIG. 14 define the positions of the following electric-conducting holes and the positions of the following cup-structure. Accordingly, the electric-conducting holes 446 and the cup-structure 38 are formed by performing a wet etching process including KOH solution, after the first patterned isolation layer 446 is formed.

As shown in FIG. 14, the first patterned isolation layer 446 may be further patterned to form openings for defining the positions of the following heat-conducting holes, and an anisotropic dry etching process is performed to form the heat-conducting holes 460. Each of the electric-conducting holes 64 and each of the heat-conducting holes 460 penetrate through the Si-substrate 62 from the top surface to the bottom surface. Following that, a second isolation layer 458, a plurality of substrate-penetrating electric-conducting wires 34a and at least a heat-conducting wire 34b are formed, and the opto-electronic package structure 36 and the printed circuit board 48 are provided, as described in the above-mentioned embodiment.

Since the etching target is made of silicon, and semiconductor etching processes are adopted. The cup-structure 38 may have a depth of substantially 100 micrometers. In other embodiment, one Si-substrate 62 can include four cup-structures 38 for loading four opto-electronic package structures 36. In such a case, each Si-substrate 62 can be 4.29 millimeters in length, 3.57 millimeters in width, and 0.4 millimeters in height; and each cup-structure 38 can be 1.417 millimeters in length and in width.

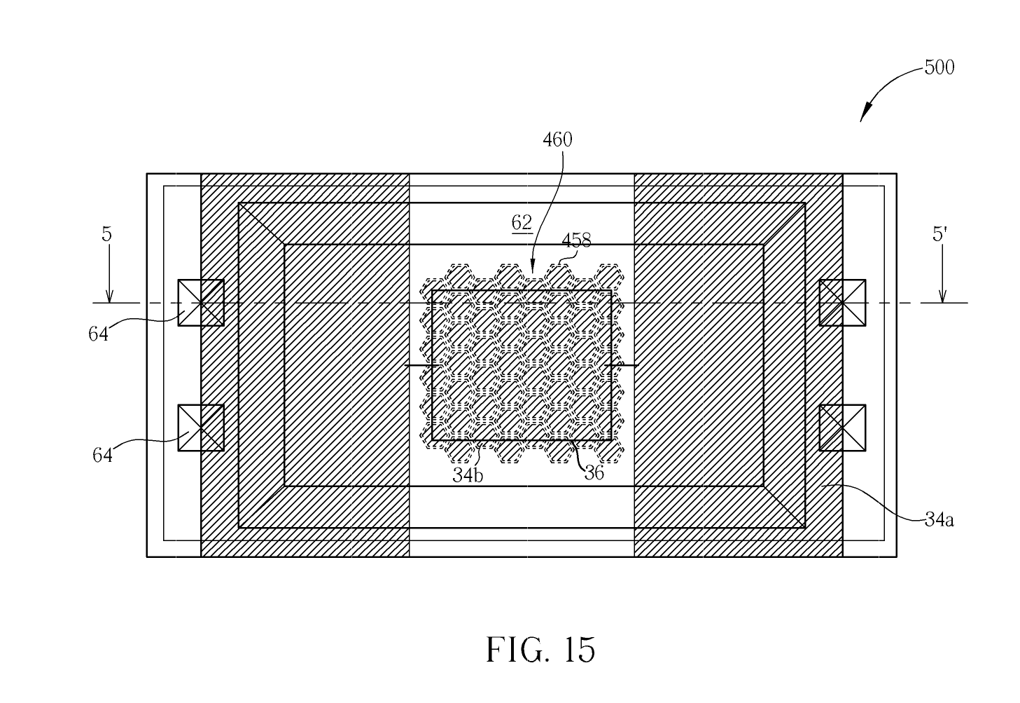

The heat-conducting holes or the heat-conducting wire may have any shapes, such as a cylinder, a cube or an octahedral structure. Please refer to FIG. 15. FIG. 15 is a schematic tip-view diagram illustrating the heat-conducting wire according to the sixth preferred embodiment of the present invention. As shown in FIG. 15, each of the heat-conducting holes 460 has a regular hexagonal cross-section, and the heat-conducting holes 460 form a honeycombed structure in the Si-substrate 62. Accordingly, a length of each side of the regular hexagonal cross-section is substantially in a range from 15 micrometers to 150 micrometers, preferably from 25 micrometers to 50 micrometers, and a distance between two heat-conducting holes 460 is substantially in a range from 10 micrometers to 50 micrometers, preferably being 20 micrometers.

According to the opto-electronic package structure of the present invention, the Si-substrate can include the thermal via and the electric via separately, so the generated heat can effectively be transferred from the opto-electronic device to the surroundings without disturbing the electric conduction. The package structure having separate thermal via and electric via can include a plat-like Si-substrate or a cup-like Si-substrate. Furthermore, the thermal via and the electric via are directly formed by filling the through holes of the Si-substrate, so the opto-electronic package structure of the present invention are more stable and firmer than a traditional package structure, which adhere to a metal layer as a thermal path. In addition, the thermal resistance of the opto-electronic package structure can be reduced to 0.06° C./W in the present invention; and the fill factor of the heat-conducting wire can be higher than 70%. The heat-conducting holes can form a honeycombed structure in the Si-substrate to ensure the great stability and the lower thermal resistance in the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An opto-electronic package structure having a silicon-substrate (Si-substrate), comprising:
a Si-substrate having a top surface and a bottom surface, comprising:
a plurality of electric-conducting holes, each of the electric-conducting holes penetrating through the Si-substrate from the top surface to the bottom surface; and
a plurality of heat-conducting holes, each of the heat-conducting holes penetrating through the Si-substrate from the top surface to the bottom surface;
a plurality of connectors, comprising:
a plurality of substrate-penetrating electric-conducting wires, each of the substrate-penetrating electric-conducting wires extending from the top surface of the Si-substrate to the bottom surface of the Si-substrate through the electric-conducting holes, and
at least a heat-conducting wire extending from the top surface of the Si-substrate to the bottom surface of the Si-substrate through the heat-conducting holes, the heat-conducting wire covering portions of the bottom surface of the Si-substrate, wherein the substrate-penetrating electric-conducting wires and the heat-conducting wire are electrically disconnected; and
at least an opto-electronic device positioned on the top surface of the Si-substrate, covering and adjusting the heat-conducting holes, corresponding to the heat-conducting wire, and electrically connected to the substrate-penetrating electric-conducting wires.

2. The opto-electronic package structure of claim 1, wherein the top surface of the Si-substrate comprises a cup-structure, and the opto-electronic device is positioned in the cup-structure.

3. The opto-electronic package structure of claim 2, wherein the electric-conducting holes penetrate portions of the Si-substrate positioned under the cup-structure.

4. The opto-electronic package structure of claim 2, wherein the electric-conducting holes penetrate portions of the Si-substrate positioned around the cup-structures.

5. The opto-electronic package structure of claim 1, wherein the substrate-penetrating electric-conducting wires positioned on the bottom surface of the Si-substrate contact a metal connecting layer, and are electrically connected to a printed circuit board through the metal connecting layer.

6. The opto-electronic package structure of claim 1, wherein a bottom of the heat-conducting wire contacts a metal connecting layer, and the metal connecting layer contacts a printed circuit board.

7. The opto-electronic package structure of claim 1, wherein the Si-substrate is substantially a flat plat.

8. The opto-electronic package structure of claim 1, wherein the opto-electronic device comprises a light emitting diode (LED).

9. The opto-electronic package structure of claim 1, wherein each of the heat-conducting holes has a regular hexagonal cross-section.

10. The opto-electronic package structure of claim 9, wherein the heat-conducting holes form a honeycombed structure in the Si-substrate.

11. The opto-electronic package structure of claim 9, wherein a length of each side of the regular hexagonal cross-section is substantially in a range from 15 micrometers to 150 micrometers.

12. The opto-electronic package structure of claim 10, wherein a distance between the heat-conducting holes is substantially in a range from 10 micrometers to 50 micrometers.

13. The opto-electronic package structure of claim 2, wherein the cup-structure has a depth of substantially 100 micrometers.

14. A method of forming an opto-electronic package structure having a silicon-substrate (Si-substrate), the method comprising:
providing a Si-substrate and a first patterned isolation layer covering at least a surface of the Si-substrate;
etching the Si-substrate through openings of the first patterned isolation layer to form a plurality of electric-conducting holes and a plurality of heat-conducting holes, each of the electric-conducting holes penetrating through the Si-substrate from the top surface to the bottom surface, each of the heat-conducting holes penetrating through the Si-substrate from the top surface to the bottom surface;
forming a patterned conductive layer filling the electric-conducting holes and the heat-conducting holes to form a plurality of substrate-penetrating electric-conducting wires and at least a heat-conducting wire respectively, each of the substrate-penetrating electric-conducting wires extending from the top surface of the Si-substrate to the bottom surface of the Si-substrate through the electric-conducting holes, the heat-conducting wire extending from the top surface of the Si-substrate to the bottom surface of the Si-substrate through the heat-conducting holes, the heat-conducting wire covering portions of the bottom surface of the Si-substrate, wherein the substrate-penetrating electric-conducting wires and the heat-conducting wire are electrically disconnected; and
providing at least an opto-electronic device on the top surface of the Si-substrate, the opto-electronic device covering and adjusting the heat-conducting holes, corresponding to the heat-conducting wire, and electrically connected to the substrate-penetrating electric-conducting wires.

15. The method of claim 14, wherein a top surface of the Si-substrate comprises a cup-structure, and the opto-electronic device is positioned in the cup-structure.

16. The method of claim 14, wherein the step of etching the Si-substrate comprises:
performing an anisotropic dry etching process to form the electric-conducting holes and the heat-conducting holes.

17. The method of claim 14, wherein the step of etching the Si-substrate comprises:
performing a wet etching process to form the electric-conducting holes; and
performing an anisotropic dry etching process to form the heat-conducting holes.

18. The method of claim 14, further comprising:
forming a second isolation layer on sidewalls of the electric-conducting holes and on sidewalls of the heat-conducting holes before forming the patterned conductive layer.

19. The method of claim 14, wherein the step of forming the patterned conductive layer comprising:
forming a seed layer on the Si-substrate; and
performing a plating process to form conductive material on the seed layer.

20. The method of claim 14, wherein each of the heat-conducting holes has a regular hexagonal cross-section and the heat-conducting holes form a honeycombed structure in the Si-substrate.
